(19) United States
(12) Patent Application Publication
(10) Pub. No.: US 2026/0171137 A1
(43) Pub. Date: Jun. 18, 2026

(54) Power Gating Circuitry and Methods

(71) Applicant: Arm Limited, Cambridge (GB)

(72) Inventors: Sumant Kumar Thapliyal, Bangalore (IN); Navin Agarwal, Bangalore (IN); Sriram Thyagarajan, Austin, TX (US); Yew Keong Chong, Austin, TX (US); Andy Wangkun Chen, Austin, TX (US)

(21) Appl. No.: 18/982,208

(22) Filed: Dec. 16, 2024

(51) Int. Cl. G11C 11/4074; G06F 1/3234; G11C 5/14; H03K 19/00

(52) U.S. Cl. CPC G11C 11/4074; G06F 1/3275; G11C 5/147; H03K 19/0016

(57) ABSTRACT

In one implementation, a circuit for power-switching includes: power gating circuitry and a first back metal, where a single output of the power gating circuitry is configured to provide at least one of power and ground supply by way of the first back metal to a word line driver circuitry. A method for power-switching includes: providing a power gating circuitry and one or more back metals; and providing, by the power gating circuitry, at least one of power and ground supply through the one or more back metals to a word line driver circuitry. A method of fabrication includes: fabricating a memory macro unit; forming one or more back metals; and coupling power gating circuitry and word line driver circuitry of the memory macro unit by way of the one or more back metals.

### I. FIELD

The present disclosure is generally related to systems, methods, and devices for power gating circuitry.

### II. DESCRIPTION OF RELATED ART

In modern semiconductor design, power management is a critical challenge, especially in circuits with high-density memory and logic components. Power gating circuitry, including headers (e.g., PMOS switches) and footers (e.g., NMOS switches), is commonly used to control power delivery selectively, allowing parts of the circuit to enter low-power or standby modes. This technique is essential for reducing leakage current and improving overall power efficiency. However, current power gating methods face significant challenges in terms of area efficiency and power integrity due to the limitations of existing circuit designs.

In one example of current state of the art, distributed word line driver designs are employed, where power gating circuitry uses headers and footers to control power to various regions of the circuit. These designs often utilize thin VDDCE/VSSE tracks in the front metal layers (e.g., M0), resulting in a high IR drop—a reduction in voltage due to the resistance of the metal lines. This IR drop can adversely affect power delivery to critical components, leading to inconsistent performance and potential failures under varying load conditions.

To address these power delivery challenges, some current approaches incorporate additional circuitry to manage power flow more effectively. However, these designs come with trade-offs. For instance, adding additional standard cells to support improved power delivery paths can help reduce IR drop but results in an approximately 5% area impact at the instance level. This extra area consumption reduces the overall density of the circuit and limits the scalability of the design, particularly in applications where space is a premium.

Hence, there is an ongoing need in the art for improved power gating circuit designs that can overcome these limitations. Specifically, there is a demand for solutions that provide better area efficiency while maintaining or enhancing power integrity, reducing IR drops, and minimizing the overall footprint of power management structures within the chip. Such advancements would enable more effective power gating in advanced integrated circuits, supporting higher performance and energy-efficient designs.

### III. BRIEF DESCRIPTION OF THE DRAWINGS

The present technique(s) will be described further, by way of example, with reference to embodiments thereof as illustrated in the accompanying drawings. It should be understood, however, that the accompanying drawings illustrate only the various implementations described herein and are not meant to limit the scope of various techniques, methods, systems, circuits or apparatuses described herein.

FIG. 1 is a diagram of an example circuit in accordance with various implementations described herein.

FIG. 2 is a diagram of an example circuit in accordance with various implementations described herein.

FIG. 3 is a diagram of an example circuit in accordance with various implementations described herein.

FIG. 4 is an operational method in accordance with various implementations described herein.

FIG. 5 is a manufacturing method in accordance with various implementations described herein.

FIG. 6 is a block diagram in accordance with various implementations described herein.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### IV. DETAILED DESCRIPTION

Implementations of the present disclosure are described below with reference to the drawings. In the description, common features are designated by common reference numbers throughout the drawings.

In one implementation, the present disclosure describes a circuit for power-switching. The circuit includes: power gating circuitry and a first back metal, where a single output of the power gating circuitry is configured to provide at least one of power and ground supply by way of the first back metal to a word line driver circuitry.

In another implementation, the present disclosure describes a circuit for power-switching. The circuit includes: a memory macro unit comprising: power gating circuitry and a first back metal, where a single output of the power gating circuitry is configured to provide at least one of power and ground by way of the first back metal to a word line driver circuitry.

In another implementation, the disclosure describes a method for power-switching. The method includes: providing a power gating circuitry and one or more back metals; and providing, by the power gating circuitry, at least one of power and ground supply through the one or more back metals to a word line driver circuitry.

In another implementation, the disclosure describes a method of fabrication. The method includes: fabricating a memory macro unit; forming one or more back metals; and coupling power gating circuitry and word line driver circuitry of the memory macro unit by way of the one or more back metals.

Certain definitions have been provided herein for reference. The term “memory macro unit” (e.g., a butterfly architecture) is a reusable, modular memory block that includes one or more memory cores (i.e., cores, bitcell array, core storage arrays, memory arrays, memory instances) along with peripheral circuitry such as address decoding logic (i.e., decoders), input/output (I/O) circuitry, word line driver circuitry and control logic. These units are typically optimized for specific applications and can be easily incorporated into system-on-chip (SoC) designs. Memory macro units provide designers with ready-made, verified memory solutions that can be quickly integrated, reducing development time and risk. They come in various sizes and types, including SRAM, DRAM, ROM, Flash, and specialized memories like multi-port RAM or content-addressable memory (CAM). Each type offers different trade-offs in terms of density, speed, power consumption, and cost, allowing designers to choose the most suitable option for their specific design requirements in modern integrated circuits. A memory core is a primary storage area of a memory chip, consisting of an organized array of memory cells arranged in rows and columns. It contains the actual storage elements that hold data, distinct from peripheral circuitry like address decoders, input/output (I/O) circuitry, and control logic. The memory core's design directly influences the memory's capacity, speed, and power consumption.

Word line driver circuitry (e.g., including a plurality of word line drivers) is a peripheral circuitry in memory systems that interfaces between the address decoding logic and the memory core. Situated at the edge of the memory core, it generates, amplifies, and transmits signals to activate specific word lines within the core, providing sufficient voltage and current for reliable memory cell activation. While essential for memory operation, word line drivers are not part of the storage elements themselves, but rather belong to the supporting circuitry along with other peripheral components like address decoders, sense amplifiers, and I/O buffers. Power gating (i.e., power switching) circuitry including power gating devices, such as a header (e.g., a PMOS power switch) connected to a power supply or a footer (e.g., an NMOS power switch) connected to ground, which can selectively disconnect inactive word line drivers to minimize leakage current in standby mode.

External Supply is the main power supply provided to the chip from an external source. It's typically a fixed voltage (e.g., 1.8V, 3.3V, etc.) supplied by the system's power management unit. It's considered “hard” because it's directly connected to the chip's power pins and is always present when the system is on. Soft Supply is an internal power net created within the chip using power gating techniques. It's called “soft” because it can be turned “on” and “off” by the chip's power management circuitry. The voltage of a soft supply is derived from the external supply but is controlled by power switches (headers or footers).

VDDCE, VDDC, VSSE, and VSS refer to different power and ground rails. VDDCE is the external supply voltage for core circuitry, while VDDC is the soft supply (i.e., internal supply) powering the core logic at a lower voltage for efficiency. VSSE is the external ground reference paired with VDDCE, and VSS is the common ground or zero-voltage reference for the entire system. In this context, VDDCE and VSSE handle external supply, whereas VDDC and VSS manage internal power and grounding. Accordingly, VDDCE and VSSE are both external supply (i.e., external power connection), while VDDC and VSS are both soft supply (i.e., internal power connection). Back metal layers (e.g., BMa, BMb; first and second back metals, an upper back metal and a lower back metal) are the uppermost conductive layers formed during the back-end-of-line (BEOL) phase of semiconductor fabrication, typically used for power delivery and signal routing. Made of materials like copper or aluminum, these layers distribute power across the chip and enable efficient signal transmission. They are part of complex interconnect networks, separated by dielectric materials, and often span multiple layers connected through vias. Back metal layers also play a role in integrating power gating devices for energy efficiency and can assist in thermal management due to their conductive properties.

Aspect ratio refers to the proportional relationship between the Contacted Poly Pitch (CPP) width and standard cell (SC) height. CPP defines the horizontal spacing of poly gates, determining the cell's width, while SC height, measured in metal tracks, dictates the vertical dimension and available routing space. The aspect ratio, calculated as CPP width over SC height (Aspect Ratio=CPP Width/SC Height), influences cell shape and layout efficiency. A higher aspect ratio indicates a wider, shorter cell, which can complicate vertical routing, while a lower aspect ratio suggests a taller, narrower cell, potentially improving routing efficiency but affecting area usage. Balancing this aspect ratio is crucial for optimizing area efficiency, routing flexibility, and performance in chip designs.

For digital circuits, especially those using power gating for low power operation, headers (e.g., for PMOS) and footers (e.g., for NMOS) are power switches used to control the power supply to different blocks of the chip. As described herein, power gating circuitry can be header circuitry, footer circuitry or both. In terms of width, contacted-poly-pitch (CPP) describes the horizontal spacing between polysilicon gates, which influences the overall width of transistors and their corresponding circuitry in a design layout. For header and footer circuitry, the width of these sections is largely determined by how tightly or loosely the transistors (or the gates of these transistors) are packed in the layout. When discussing CPP in terms of the width of header, footer, and transition sections, it refers to the horizontal spacing between polysilicon gates that determines the overall width of these circuit sections. The smaller the CPP, the narrower and more compact the header/footer and transition sections can be, allowing for higher transistor density and more efficient use of layout space.

Inventive aspects of the present invention provide significant advantages by enabling the use of a wider (“fat”) back metal for routing power and ground from a central header and footer circuitry directly to all word line drivers. This wider back metal layer, with lower load resistance, allows for efficient distribution of power across the word line driver circuitry, reducing IR drop (e.g., to approximately 10 mV), which is substantially lower than the resistance typically encountered with front metal layers. Advantageously, by big header and footer circuitry within the control circuitry and leveraging the back metal's capacity for broad, low-resistance power delivery, innovative designs, as described herein, achieve more stable voltage levels and consistent power distribution. This improvement addresses limitations in conventional designs, where narrower front metal layers introduce higher resistance and IR drop, compromising power integrity and performance.

Inventive approaches, as described herein, optimize area efficiency and power integrity by using back metal layers to deliver external supply (e.g., VDDCE and VSSE) and internal supply (VDDC and VSS). As a result, the designs reduce the space needed for power distribution, creating more compact layouts and significantly reducing IR drop, or voltage loss due to line resistance. For example, the reduction in IR drop provides a more stable and consistent power supply, improving the circuit's reliability and performance under varying load conditions.

One implementation features a top/bottom (e.g., “stacked”) configuration for power delivery, while another uses a side-by-side (e.g., lateral, coplanar) configuration, each suited to specific design requirements. These configurations leverage the lower resistance of back metal layers, enhancing voltage stability and power integrity, which is especially advantageous for complex SoCs where space and power efficiency are crucial. Inventive aspects also include a shared track (e.g., shared header/footer configuration) within the back metal (e.g., BMa) for external and internal supply connections, further reducing the size of the power management circuitry and achieving an 11% area savings, for example, per unit cell. In such an example, the compact design enables the creation of wd2ck_mid cells with 8 Contacted Poly Pitch (CPP), offering significant improvement over conventional designs.

Advantageously, these innovations directly address the challenges of high IR drop and excessive area consumption found in current methods. By reducing IR drop and minimizing space requirements, the disclosed designs enable more efficient power delivery and enhanced performance, making them well-suited for modern, high-performance integrated circuits.

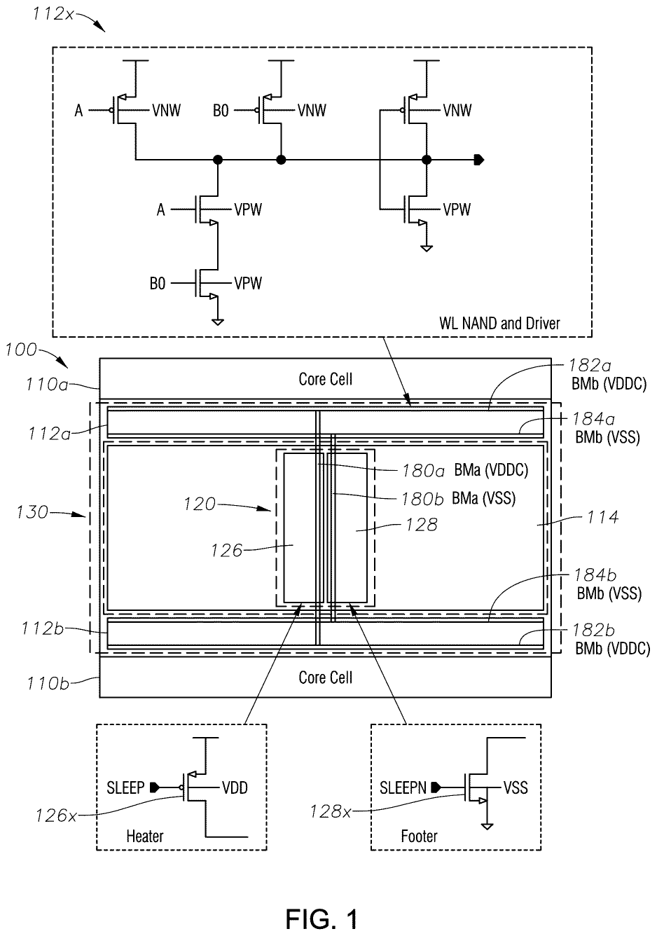

Referring to FIG. 1, a memory macro unit 100 according to example implementations is shown. As illustrated, the memory macro unit 100 (e.g., a butterfly architecture) may include one or more memory cores 110 (e.g., first and second cores 110a, 110b) and peripheral circuitry 120 coupled to the one or more memory cores 110. As illustrated, the peripheral circuitry 120 includes: at least word line driver circuitry 112 (e.g., WL NAND and Driver) (e.g., first and second word line drivers 112a, 112b), and control circuitry 114, where the control circuitry 114 may be coupled adjacent to the one or more memory cores 110. In certain implementations, power gating circuitry 120 is included within the control circuitry 114. For example, as described herein, the power gating circuitry 120 includes a non-distributed, “single” entity (e.g., “lumped’) header and footer combination design, including a header circuitry 126 (e.g., a “big” header; a “lumped” header block), and a footer circuitry 128 (e.g., a “big” footer; a “lumped” footer block). As may be appreciated, “non-distributed” in this context refers to components or systems that are centralized, lumped, or concentrated in a single physical location or area (e.g., control circuitry 114), rather than being spread out or distributed across a larger region or structure (e.g., word line driver circuitry 112 distributed across the memory macro unit 100). In various cases, a single output of the power gating circuitry 238 can be configured to provide at least one of power and ground supply (e.g., VDDC and VSS) to the word line driver circuitry (e.g., 112a, 112b) by way of a first back metal (BMa) 180 (e.g., 180a, 180b).

In certain implementations, a second back metal (BMb) (e.g., 182a, 182b, 184a, 184b) can be coupled to the first back metal (BMa) (e.g., 180a coupled to 182a, 182b; 180b coupled to 184a, 184b) by vias. By doing so, the single output of the power gating circuitry may can be configured to provide at least one of power and ground supply by way of both the first and second back metals to each of a plurality of word line drivers of the world line driver circuitry (e.g. 112a, 112b). Advantageously, in such implementations, the single output of the power gating circuitry 120 (e.g., centralized single entity) can be routed to each of the word line drivers (e.g., all of the word line NAND and drivers) of the circuit 100. Similarly, in other implementations (not shown), where the power gating circuitry (e.g., centralized single entity) includes just header circuitry 126 or just footer circuitry 128, the single output of such power gating circuitry may also be routed to each of the word line drivers (e.g., all of the word line NAND and drivers) of the circuit 100.

Moreover, as illustrated while the first back metal (BMa) includes segments for both the first back metal for power supply, VDDC (180a BMa VDDC) and the first back metal for ground supply, VSS (180b BMa, VSS), such segments of the first back metal 180 BMa VDDC and the first back metal 180b VSS would never intersect (e.g., never connect or never be coupled). Similarly, as shown, the second back metal for power supply, VDDC (BMb 182a, BMb 182b) would never intersect with the second back metal for ground supply, VSS (BMb 184a, BMb, 184b).

In addition, in various cases, the power gating circuitry 120 (e.g., power-switching circuitry) can be configured to receive internal and/or external supply through at least the first back metal (BMa) 180 (e.g., 180a, 180b). In addition, in some implementations, the power gating circuitry 120 may be disposed and formed on the first back metal (BMa) 180. In certain implementations, the peripheral circuitry 130 includes: address decoding logic (i.e., one or more word-line decoder blocks) (not shown), where the control circuitry 114 is coupled to the address decoding logic; and respective input/output (I/O) circuitry (not shown) for each of the one or more memory cores 110. In such examples, each of the I/O circuitry (not shown) can include sense amplifier circuitry, a pre-charge circuit, a column multiplexer, and input and output latches. For instance, in a butterfly architecture, the I/O circuitry (not shown) may be placed adjacent to the one or more memory cores 110, and the address decoding logic (not shown) may be placed adjacent to the control logic 114. As illustrated, for each word line, the word line driver circuitry 112 may include a combination of NAND gate and inverter configurations 112x. As may be appreciated, such a configuration can allow precise control over when a word line is activated. In an example, the NAND gate helps with conditional activation based on address and control signals, while the inverter ensures the output is suitable for driving the word line effectively.

In various implementations, the header circuitry 126 of the power gating circuitry 120 includes a plurality of unit PMOS devices 116x (e.g., a plurality of PMOS transistors non-distributed as single entity (i.e., “big” header)), while footer circuitry 128 of the power gating circuitry 120 includes a plurality of unit NMOS devices 118x (e.g., a plurality of NMOS transistors non-distributed as a single entity (i.e., “big” footer)). According to various examples, the power gating circuitry 120 may be coupled to each of the plurality of word line drivers 112a, 112b of the

### Word Line Driver Circuitry 112.

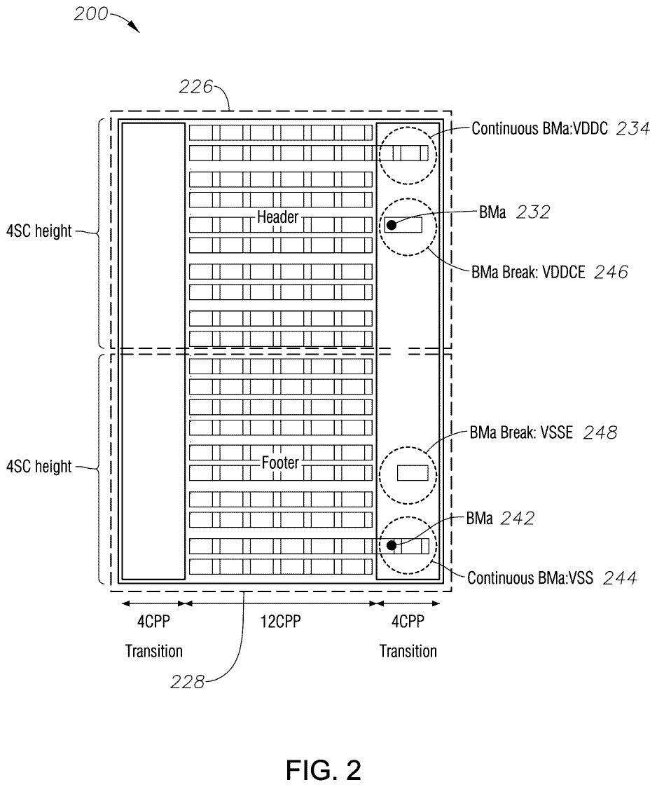

Referring to FIG. 2, an example circuit design 200 according to example implementations is shown in a side view. As illustrated, the example circuit design 200 (e.g., power gating circuitry 200) corresponds to “top/bottom” (e.g., stacked) design of one unit standard cell “entity” of the power gating circuitry 120 shown in the X-Z direction. In various implementation, the unit standard cell unit entity would repeated a plurality of times in an adjacent instance level placement arrangement to form a “lumped” circuit design.

As depicted, the power gating circuitry 200 in the “top/down” (e.g., stacked) design includes the header circuitry 226 arranged above the footer circuitry 228. In one implementation, as shown, the power gating circuitry 200 includes a height of approximately eight standard cells, where each of the header circuitry 226 and the footer circuitry 228 includes a height of approximately four standard cells. Moreover, for example, each of the header circuitry 226 and the footer circuitry 228 includes a horizontal spacing (e.g., width) of approximately twelve contacted-poly-pitch (CPP). Hence, for instance, each unity entity of the power gating circuitry 200 includes a horizontal spacing (e.g., width) of approximately twenty contacted-poly-pitch (CPP), where 4 CPP is required for transition spacing on each side.

In one example case, as shown, the power gating circuitry 200 may be configured for internal supply through a first back metal (e.g., first back metal layer, BMa); for example, for the header circuitry 226 at BMa 232 and for the footer circuitry 228 at BMa 242. Also, as illustrated, the first back metal (e.g., BMa) may be a continuous metal layer (i.e., continuous metal network) for internal supply coupling (e.g. continuous BMa: VDDC 234 and continuous BMa: VSS 244) for both the header and the footer circuitry 226, 228. However, the first back metal (e.g. BMa) is not continuous for external supply (e.g., BMa break: VDDCE 236 and BMa break: VSSE 246).

Advantageously, the proposed top/bottom design approach, utilizing back metal for external supply (VDDCE and VSSE), significantly reduces IR drop by providing a low-resistance path for power delivery. This design ensures more stable voltage levels across the circuit, enhancing power integrity and improving overall performance.

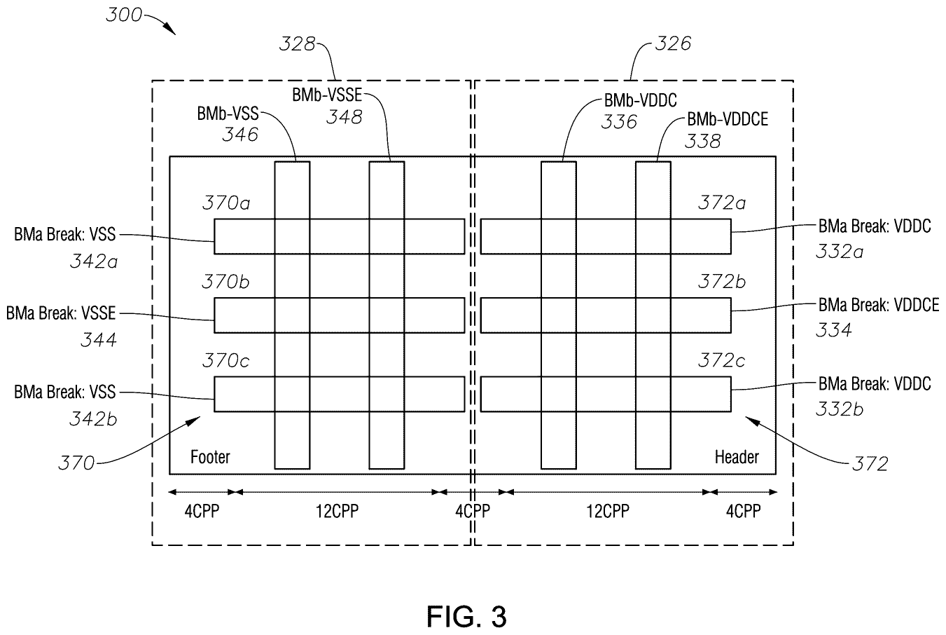

Referring to FIG. 3, an example circuit design 300 according to example implementations is shown in a top view. As illustrated, the example circuit design 300 (e.g., power gating circuitry 300) corresponds to a “side-by-side” (e.g., lateral) design of one unit standard cell “entity” of the power gating circuitry 120 shown in the X-Y direction. In various implementation, the unit standard cell unit entity would be repeated a plurality of times in an adjacent placement arrangement to form a “lumped” circuit design.

As depicted, the power gating circuitry 300 in the side-by-side design includes the header circuitry 326 arranged side-by-side (e.g., adjacent) to the footer circuitry 328. In one implementation, as shown, the power gating circuitry 300 includes a height of approximately four standard cells, where each of the header circuitry 326 and the footer circuitry 328 includes a height of approximately four standard cells. Moreover, for example, each of the header circuitry 326 and the footer circuitry 328 includes a horizontal spacing (e.g., width) of approximately twelve contacted-poly-pitch (CPP). Hence, for instance, each unity entity of the power gating circuitry 300 includes a horizontal spacing (e.g., width) of approximately thirty-six contacted-poly-pitch (CPP), where 4 CPP is required for transition spacing on each end, and 4 CPP is shared to separate the header circuitry 326 and the footer circuitry 328.

In one example case, as shown, the power gating circuitry 300 may be configured for external and internal supply through a first back metal (e.g., first back metal layer, BMa). For example, the header circuitry 326 can be configured for internal voltage supply VDDC 332 (e.g., 332a, 332b) as well as external voltage supply VDDCE 334. Similarly, the footer circuitry 328 can be configured for internal ground supply VSS 342 (e.g., 342a, 342b) as well as external ground supply VSSE 344. In addition, the power gating circuitry 300 may also be configured for both external and internal supply through a second back metal (e.g., second back metal layer, BMb). For example, for the header circuitry 326 can be configured for internal voltage supply VDDC 336 as well as external voltage supply VDDCE 338. Similarly, the footer circuitry 328 can be configured for internal ground supply VSS 346 as well as external ground supply VSSE 348.

As illustrated, as per inventive aspects, the first back metal (e.g., BMa) includes first and second segments 370, 372. As may be appreciated, advantageously, as separate and distinct portions, the first segment 370 (e.g., 370a, 370b, 370c) can used for footer circuitry 328 and the second segment 372 (e.g., 372a, 372b, 372c) can be used for header circuitry 326.

Advantageously, the side-by-side approach, featuring a shared track of back metal for both external and internal supply connections, achieves significant IR drop reduction while maintaining efficient power delivery. This design offers improved area efficiency, providing approximately a 5% area gain at the memory instance level, allowing for more compact and dense circuit layouts.

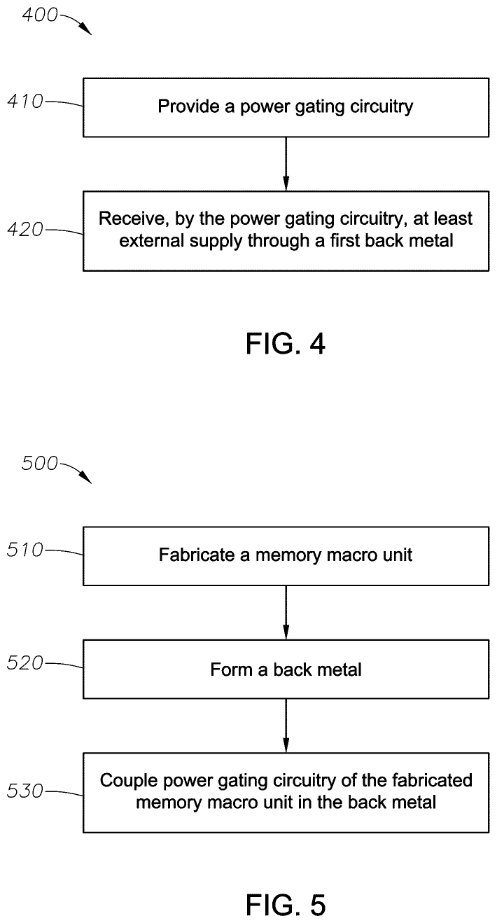

In addition, while both the top-bottom approach (FIG. 3) (e.g., vertical stacking) and the side-by-side approach (FIG. 4) (e.g., horizontal stacking) improves on existing known designs as explained herein, the side-by-side approach provides a greater aspect ratio in comparison to the top-bottom approach. Advantageously, due to the wider design (e.g., ground (VSS) on one side and power (VDDC) on the other side), there would more room for routing, and hence, routing would be easier. Also, as there would be less overall area usage, a greater quantity of headers and footers may be incorporated within given design parameters.

Referring to FIG. 4, a flowchart of an example operational method 400 (i.e., procedure) for power-switching, power delivery and distribution is shown. Advantageously, in various implementations, the method 400 describes the capability of power gating circuitry to utilize external and internal supply using one or more back metal layers. The method 400 may be implemented with reference to circuit implementation as shown in FIGS. 1-3.

At block 410, the example method 400 includes: providing a power gating circuitry and a first back metal. For instance, as described with reference to FIGS. 1-3, a power gating circuitry (e.g., power gating circuitry 120, 200, 300) and a first back metal (e.g., back metal (BMa)) may be provided.

At block 420, the example method 400 includes: providing, by the power gating circuitry, at least one of power and ground supply through the one or more back metals to a word line driver circuitry. For instance, as described with reference to FIGS. 1-3, the power gating circuitry (e.g., power gating circuitry 120, 200, 300) may provide at least one of power and ground supply (VDDC and/or VSS) through the one or more back metals (e.g., BMa, BMb) to a word line driver circuitry (e.g., 112a, 112b)

In certain implementations, as described herein, the method 400 further includes: providing a memory macro unit (e.g., memory macro unit 100). As one example, the memory macro unit includes: one or more memory cores 110, and peripheral circuitry 130 coupled to the one or more memory cores 110. For instance, the peripheral circuitry 130 can include address decoding logic (i.e., one or more word-line decoder blocks); word line driver circuitry configured to interface between the address decoder logic and the one or more memory cores; control circuitry coupled to the address decoding logic; and respective input/output (I/O) circuitry for each of the one or more memory cores. In certain cases, each I/O circuitry includes sense amplifier circuitry, a pre-charge circuit, a column multiplexer, and input and output latches.

Referring to FIG. 5, a flowchart of an example formation method 500 (i.e., procedure) for power gating (e.g., power-switching), power delivery and distribution via one or more back metals (e.g., back metal layer; BMa, BMb) is shown. Advantageously, in various implementations, the method 500 depicts the fabrication method steps for a three-dimensional semiconductor stack. The method 500 may be implemented with reference to circuit implementations as shown in FIGS. 1-3.

At block 510, the method 500 includes: fabricating a memory macro unit. For instance, with reference to various implementations as described in FIGS. 1-3, a memory macro unit (100) may be fabricated from a multi-step sequence of photolithographic and chemical processing steps (such as surface passivation, thermal oxidation, planar diffusion, and junction isolation) during which electric circuits are gradually created on a wafer made of semiconducting material.

At block 520, the method 500 includes: forming one or more back metals. For instance, with reference to various implementations as described in FIGS. 1-3, one or more back metals (e.g., first and second back metal layers; BMa, BMb) may be formed by etching a metal trench in an interlayer dielectric (ILD), filling the metal trench with copper or aluminum, and fabricating back-end-of-line (BEOL) wiring to be coupled to the one or more back metals (e.g., BMa, BMb).

At block 530, the method 500 includes: coupling power gating circuitry and word line driver circuitry of the memory macro unit by way of the one or more back metals. In certain cases, the power gating circuitry may be formed in the back metal itself.

Moreover, in some cases, the method 500 further includes: removing a layer from a back portion of the ILD to reveal the back metal. For example, the process of removing a layer from the back portion of the inter-layer dielectric (ILD) to reveal the back metal involves applying a protective coating, followed by photolithography to define an area of exposure. An anisotropic dry etching process, such as reactive ion etching (RIE), is then used to precisely remove the ILD above the back metal, with endpoint detection ensuring the etching stops when the back metal is exposed. Optionally, a selective wet etch may be applied to clean any remaining ILD residue, followed by plasma or wet cleaning to ensure the surface is free of contaminants. The exposed back metal is then inspected using microscopy to verify proper exposure and readiness for further processing. Advantageously, such a method step ensures precise access to the back metal layer, facilitating electrical connections or additional integration steps.

In certain implementations, forming power gating circuitry directly in the back metal layers involves embedding power-switching structures during the back-end-of-line (BEOL) process, without relying on transistors in the silicon substrate or using vias. Such a process starts with designing the layout for power-switching regions within the back metal. Photolithography can be used to pattern trenches in the dielectric layers, defining areas for selective metal deposition, such as copper, to create switchable bridges that control power flow for external and internal supply (e.g., VDDCE, VDDC, VSSE and VSS). These conductive paths may act as programmable switches within the metal layers. To ensure durability, electro-migration barriers like tantalum nitride are added during deposition. Insulated gaps can be formed using dielectric materials to create regions where power paths remain disconnected until activated. Switching can be achieved by applying localized heating or electric fields to materials such as phase-change materials, enabling changes between conductive and resistive states. A final metallization layer may be deposited and planarized for a smooth surface, followed by applying a passivation layer to protect the power-switching structures. Advantageously, such an approach would allow for compact, efficient power control directly within the back metal, ideal for advanced memory and SoC designs.

In other implementations, forming power gating circuitry in back metal layers involves integrating header (e.g., PMOS) and footer (e.g., NMOS) transistors with the power distribution network during the back-end-of-line (BEOL) stage of semiconductor fabrication. The process enables the management of both external supply (VDDCE and VSSE) and internal supply (VDDC and VSS), allowing for precise control of power distribution within the memory macro unit. For example, the process begins with the design and layout of the circuitry and determining the placement of power gating transistors and their connections to back metal layers. Header and footer transistors may be first fabricated in the silicon substrate during the front-end-of-line (FEOL) process. In such examples, after transistor formation, interconnect layers and vias may be created to establish vertical connections between these transistors and the metal layers. Trenches can be etched into the dielectric layers above the transistors to define the shape of the back metal power rails. These trenches are filled with conductive materials like copper through deposition techniques, forming the rails for VDDCE, VDDC, VSSE, and VSS in the back metal layer(s).

For instance, vias can provide connections between the source, drain, and gate terminals of the transistors and the back metal layers, allowing headers and footers to regulate the flow of power between the external and internal supplies. The gate terminals of the headers and footers are connected to control logic that manages the power gating operation, enabling selective power delivery to different parts of the memory macro unit depending on the operational state. In addition, the back metal layers may be then patterned and etched to ensure the correct configuration and isolation of power rails, enabling them to support both external and internal supply needs. A passivation layer is applied to protect the metal layers from environmental damage, with openings created for external connections during packaging. After assembly, the device would undergo testing to ensure that the power gating functions correctly, effectively managing leakage currents and switching behavior between the external and internal supplies. The final packaged device connects the back metal power rails to external power sources, providing a robust, low-resistance pathway for managing power flow through the headers and footers. This integration supports efficient power management, enabling precise control of external and internal supply in high-performance memory designs.

Also, according to aspects of certain operational methods, an output may be generated based on the operational dispositions. For example, with reference to various implementations as described in FIGS. 1-3, an output, such as an integrated circuit design (e.g., (e.g., a memory architecture, multi-threshold offerings for memory compilers) may be generated. In some implementations, the electronic design automation (EDA) tool 624 (e.g., incorporating a circuit design tool) may allow users to input certain values, and generate circuit designs incorporating the inventive “lumped” power gating circuitry design(s). Such a tool 524 may be focused on the creation, analysis, and verification of such electronic circuits.

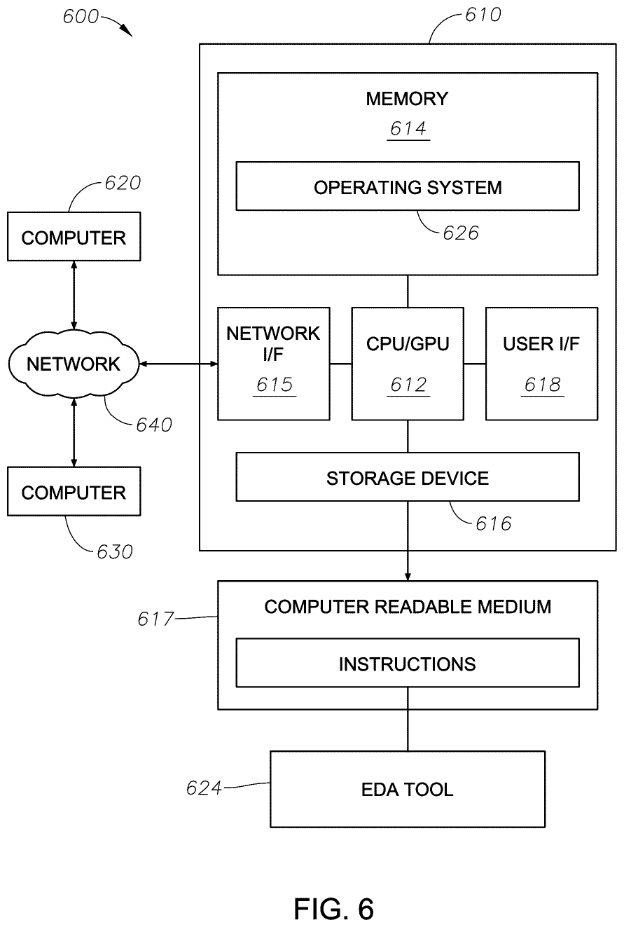

FIG. 6 illustrates example hardware components in the computer system 600 that may be used to facilitate and generate the inventive circuit design/memory architecture output. In certain implementations, the example computer system 600 (e.g., networked computer system and/or server) may include EDA tool 624 and execute software based on the procedure as described with reference to the methods as described herein.

In certain implementations, the EDA tool 624 begins by interpreting the design specifications outlined in the operational method, which includes the integration of power gating circuitry that manages both external and internal supplies (VDDCE, VSSE, VDDC, and VSS) using back metal layers. The EDA tool 624 first creates the layout for the power gating circuitry, incorporating header (PMOS) and footer (NMOS) switches directly into the back metal layers (e.g., BM0, BM1). These metal layers would be configured to provide pathways for selective power switching, allowing the headers and footers to connect or disconnect power lines as needed. Next, for example, the EDA tool 524 designs the memory macro unit layout, including: memory cores, address decoding logic, word line driver circuitry, and input/output (I/O) components. The memory cores provide storage, while the address decoding logic determines which memory cells are accessed. The word line driver circuitry interfaces with the decoders to activate specific word lines, and the I/O circuitry includes elements like sense amplifiers and pre-charge circuits for data transfer. The EDA tool 624 ensures these components are arranged efficiently to minimize delays and optimize signal paths.

Subsequently, in some cases, the EDA tool 624 integrates control logic that interfaces with the power gating circuitry. This logic controls when the header and footer switches within the back metal layers engage or disengage, enabling dynamic control of power flow for the external supply (VDDCE and VSSE) and the internal supply (VDDC and VSS) to different parts of the memory macro unit. Advantageously, this control ensures power is only delivered where needed, reducing power consumption during standby or low-power states. After generating the initial layout, for instance, the EDA tool 624 runs simulations to verify that the power gating functionality operates correctly. These simulations ensure that the power gating elements in the back metal respond properly to control signals, effectively switching without introducing electrical noise or excessive delays. Advantageously, the EDA tool 624 may adjust the layout based on these simulations, refining the size of metal paths, the arrangement of power-switching regions, or the positioning of control logic to optimize for power efficiency, area usage, and performance.

Also, in certain cases, the EDA tool 624 produces the complete physical layout of the design, detailing the precise placement and configuration of each element, including masks for each metal layer. This layout would now be ready for fabrication, allowing semiconductor manufacturers to create the physical chip with power gating circuitry directly embedded in the back metal layers. Advantageously, the result is a design that efficiently manages power distribution across the memory macro unit, leveraging the back metal layers for seamless integration of external and internal supplies while maintaining high performance and low power consumption.

Using the procedure 400, for example, the EDA tool 524 may provide generated computer-aided physical layout designs for “lumped” power gating circuitry and/or memory architecture. The procedure 400, for example, may be stored as program instructions as instructions 617 in the computer readable medium of the storage device 616 (or alternatively, in memory 614) that may be executed by the computer 610, or networked computers 620, 630, other networked electronic devices (not shown) or a combination thereof. In certain implementations, each of the computers 610, 620, 630 may be any type of computer, computer system, or other programmable electronic device. Further, each of the computers 610, 620, 630 may be implemented using one or more networked computers, e.g., in a cluster or other distributed computing system.

In certain implementations, the system 600 may be used with semiconductor integrated circuit (IC) designs that contain all standard cells, all blocks or a mixture of standard cells and blocks. In a particular example implementation, the system 600 may include in its database structures: a collection of cell libraries, one or more technology files, a plurality of cell library format files, a set of top design format files, one or more Open Artwork System Interchange Standard /ASIS/ OASIS. MASK) files, and/or at least one EDIF file. The database of the system 600 may be stored in one or more of memory 614 or storage devices 616 of computer 610 or in networked computers 620, 630.

In one implementation, the computer 600 includes a central processing unit (CPU) 612 (or graphics processing unit (GPU) 612 in certain implementations) having at least one hardware-based processor coupled to a memory 614. The memory 614 may represent random access memory (RAM) devices of main storage of the computer 610, supplemental levels of memory (e.g., cache memories, non-volatile or backup memories (e.g., programmable or flash memories)), read-only memories, or combinations thereof. In addition to the memory 614, the computer system 600 may include other memory located elsewhere in the computer 610, such as cache memory in the CPU 612, as well as any storage capacity used as a virtual memory (e.g., as stored on a storage device 616 or on another computer coupled to the computer 610).

The computer 610 may further be configured to communicate information externally. To interface with a user or operator (e.g., a circuit design engineer), the computer 610 may include a user interface (I/F) 618 incorporating one or more user input devices (e.g., a keyboard, a mouse, a touchpad, and/or a microphone, among others) and a display (e.g., a monitor, a liquid crystal display (LCD) panel, light emitting diode (LED), display panel, and/or a speaker, among others). In other examples, user input may be received via another computer or terminal. Furthermore, the computer 610 may include a network interface (I/F) 615 which may be coupled to one or more networks 640 (e.g., a wireless network) to enable communication of information with other computers and electronic devices. The computer 560 may include analog and/or digital interfaces between the CPU 612 and each of the components 614, 615, 616, and 618. Further, other non-limiting hardware environments may be used within the context of example implementations.

The computer 610 may operate under the control of an operating system 626 and may execute or otherwise rely upon various computer software applications, components, programs, objects, modules, data structures, etc. (such as the programs associated with the procedure 400 and related software). The operating system 628 may be stored in the memory 614. Operating systems include, but are not limited to, UNIX® (a registered trademark of The Open Group), Linux® (a registered trademark of Linus Torvalds), Windows® (a registered trademark of Microsoft Corporation, Redmond, WA, United States), AIX® (a registered trademark of International Business Machines (IBM) Corp., Armonk, NY, United States) i5/OS® (a registered trademark of IBM Corp.), and others as will occur to those of skill in the art. The operating system 626 in the example of FIG. 6 is shown in the memory 614, but components of the aforementioned software may also, or in addition, be stored at non-volatile memory (e.g., on storage device 616) and/or the non-volatile memory (not shown). Moreover, various applications, components, programs, objects, modules, etc. may also execute on one or more processors in another computer coupled to the computer 610 via the network 640 (e.g., in a distributed or client-server computing environment) where the processing to implement the functions of a computer program may be allocated to multiple computers 620, 630 over the network 640. In example implementations, circuit related diagrams have been provided in FIGS. 1-3, whose redundant description has not been duplicated in the related description of analogous circuit related diagrams. It is expressly incorporated that the same diagrams with identical symbols and/or reference numerals are included in each of embodiments based on its corresponding figure(s).

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++or the like, and procedural programming languages, such as the “C” programming language or similar programming languages. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry, field-programmable gate arrays (FPGA), or programmable logic arrays (PLA) may execute the computer-readable program instructions by utilizing state information of the computer-readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, where such instructions may execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

In the following description, numerous specific details are set forth to provide a thorough understanding of the disclosed concepts, which may be practiced without some or all of these particulars. In other instances, details of known devices and/or processes have been omitted to avoid unnecessarily obscuring the disclosure. While some concepts will be described in conjunction with specific examples, it will be understood that these examples are not intended to be limiting.

Unless otherwise indicated, the terms “first”, “second”, etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Reference herein to “one example” means that one or more feature, structure, or characteristic described in connection with the example is included in at least one implementation. The phrase “one example” in various places in the specification may or may not be referring to the same example.

Illustrative, non-exhaustive examples, which may or may not be claimed, of the subject matter according to the present disclosure are provided below. Different examples of the device(s) and method(s) disclosed herein include a variety of components, features, and functionalities. It should be understood that the various examples of the device(s) and method(s) disclosed herein may include any of the components, features, and functionalities of any of the other examples of the device(s) and method(s) disclosed herein in any combination, and all such possibilities are intended to be within the scope of the present disclosure. Many modifications of examples set forth herein will come to mind to one skilled in the art to which the present disclosure pertains having the benefit of the teachings presented in the foregoing descriptions and the associated drawings.

Therefore, it is to be understood that the present disclosure is not to be limited to the specific examples illustrated and that modifications and other examples are intended to be included within the scope of the appended claims. Moreover, although the foregoing description and the associated drawings describe examples of the present disclosure in the context of certain illustrative combinations of elements and/or functions, it should be appreciated that different combinations of elements and/or functions may be provided by alternative implementations without departing from the scope of the appended claims. Accordingly, parenthetical reference numerals in the appended claims are presented for illustrative purposes only and are not intended to limit the scope of the claimed subject matter to the specific examples provided in the present disclosure.

What is claimed is:

1. A circuit comprising:
power gating circuitry; and
a first back metal, wherein an output of the power gating circuitry is configured to provide at least one of power and ground supply by way of the first back metal to a word line driver circuitry.

2. The circuit of claim 1, wherein:
the power gating circuitry comprises a header circuitry, a footer circuity, or both;
the header circuitry comprises a plurality of PMOS devices; and
the footer circuitry comprises a plurality of NMOS devices.

3. The circuit of claim 2, wherein:
the power gating circuity is located in a control circuity of a memory macro unit; and
the control circuitry is coupled adjacent to one or more memory cores.

4. The circuit of claim 1, wherein:
the power gating circuitry is arranged in a non-distributed location of a memory macro unit, and
the word line driver circuitry is distributed across the memory macro unit.

5. The circuit of claim 1, further comprising:
a second back metal, wherein the output of the power gating circuitry is configured to provide at least one of power and ground supply by way of the first and second back metals to each word line driver of the world line driver circuitry.

6. The circuit of claim 1, wherein:
the output of the power gating circuitry is coupled to each of a plurality of word line drivers of the word line driver circuitry.

7. The circuit of claim 1, wherein:
the power gating circuitry is configured to receive internal supply through the first back metal; and
the first back metal comprises a continuous metal layer for the internal supply in both header and footer circuitry.

8. The circuit of claim 1, wherein:
the power gating circuitry comprises a header circuitry and a footer circuity; and
the header circuitry is arranged above the footer circuitry.

9. The circuit of claim 1, wherein:
the power gating circuitry is configured for both the external supply and internal supply through the first back metal;
the power gating circuitry is configured for both the external supply and the internal supply through a second back metal;
the first back metal comprises first and second segments; and
the first segment is used for footer circuitry and the second segment is used for header circuitry.

10. The circuit of claim 1, wherein:
the power gating circuitry comprises a header circuitry and a footer circuity; and
the header circuitry is arranged adjacent to the footer circuitry.

11. The circuit of claim 10, wherein the header circuitry and the footer circuitry are laterally arranged.

12. The circuit of claim 10, wherein the header circuitry and the footer circuitry are coplanar.

13. A circuit of claim 1, wherein the power gating circuitry is comprised within a memory macro unit.

14. The circuit of claim 13, wherein the memory macro unit comprises:
one or more memory cores; and
peripheral circuitry coupled to the one or more memory cores, wherein the peripheral circuitry comprises:
address decoding logic;
word line driver circuitry configured to interface between the address decoder logic and the one or more memory cores;
control circuitry coupled to the address decoding logic; and
respective input/output (I/O) circuitry for each of the one or more memory cores, wherein each of the I/O circuitry comprises sense amplifier circuitry, a pre-charge circuit, a column multiplexer, and input and output latches.

15. A method comprising:
providing power gating circuitry and one or more back metals; and
providing, by the power gating circuitry, at least one of power and ground supply through the one or more back metals to a word line driver circuitry.

16. The method of claim 15, wherein:
the power gating circuitry comprises a header circuitry, a footer circuity, or both;
the header circuitry comprises a plurality of PMOS devices; and
the footer circuitry comprises a plurality of NMOS devices.

17. The circuit of claim 16, wherein:
the power gating circuity is located in a control circuity of a memory macro unit; and
the control circuitry is coupled adjacent to one or more memory cores.

18. A method comprising:
fabricating a memory macro unit;
forming one or more back metals; and
coupling power gating circuitry and word line driver circuitry of the memory macro unit by way of the one or more back metals.

19. The method of claim 18, wherein the one or more back metals are formed by:
etching a metal trench in an interlayer dielectric (ILD);
filling the metal trench with copper; and
fabricating back-end-of-line (BEOL) wiring to be coupled to the back metal.

20. The method of claim 19, further comprising:
removing a layer from a back portion of the ILD to reveal the back metal.
